(19) United States
(12) Patent Application Publication
(10) Pub. No.: US 2016/0079478 A1
(43) Pub. Date: Mar. 17, 2016

(54) SEMICONDUCTOR LIGHT EMITTING DEVICE PACKAGE

(71) Applicant: SAMSUNG ELECTRONICS CO., LTD., Suwon-si (KR)

(72) Inventors: Bo Hyun KONG, Osan-si (KR); Young Min PARK, Hwaseong-si (KR); Dong Hyun CHO, Suwon-si (KR)

(21) Appl. No.: 14/696,239

(22) Filed: Apr. 24, 2015

(30) Foreign Application Priority Data
Sep. 15, 2014 (KR) 10-2014-0121984

(51) Int. Cl. H01L 33/38; H01L 33/32; H01L 33/58; H01L 33/40; H01L 33/06; H01L 33/42

(52) U.S. Cl. CPC H01L 33/385; H01L 33/06; H01L 33/42; H01L 33/58; H01L 33/405; H01L 33/32

(57) ABSTRACT

A semiconductor light emitting device package may include: a package body having first and second electrode structures; and a light emitting diode chip mounted on the second electrode structure of the package body, the light emitting diode chip including: a support substrate, a light emitting structure including a second conductivity type semiconductor layer, an active layer and a first conductivity type semiconductor layer sequentially stacked on the support substrate, a transparent electrode layer disposed on the first conductivity type semiconductor layer, and an insulating layer disposed on at least a side surface of the light emitting structure. The transparent electrode layer and the first electrode structure may be connected to each other by a side electrode disposed on a side surface of the light emitting diode chip.

### CROSS-REFERENCE TO RELATED APPLICATION

This application claims priority to Korean Patent Application No. 10-2014-0121984 filed on Sep. 15, 2014, with the Korean Intellectual Property Office, the disclosure of which is incorporated herein by reference.

### TECHNICAL FIELD

The present disclosure relates to a semiconductor light emitting device package.

### BACKGROUND

Semiconductor light emitting devices such as light emitting diodes (LEDs), devices containing a light emitting material therein to emit light, may convert energy generated due to the recombination of electrons and electron holes into light to be emitted therefrom. Such LEDs are currently in widespread use in lighting elements, display devices and light sources, and the development thereof has accordingly been accelerated.

In particular, in accordance with the commercialization of apparatuses such as cellular phone keypads, turn signal lamps, camera flashes and the like, using gallium nitride (GaN)-based LEDs of which the development and applications thereof have matured, general lighting devices using a light emitting diode have recently been actively developed. In products to which a light emitting diode is applied, such as large scale TV backlight units, vehicle headlamps, general lighting devices and the like, the use thereof has progressed from small portable products to large scale products having high outputs and high efficiency. Therefore, light sources exhibiting characteristics required for a corresponding product have been demanded.

As described above, in accordance with an increase in usage of semiconductor light emitting devices, methods of simplifying a production process of the semiconductor light emitting device to improve productivity and significantly decreasing the loss of light emitting regions have requested.

### SUMMARY

An exemplary embodiment of the present inventive concept may provide a semiconductor light emitting device package allowing for a simplification of a manufacturing process thereof by skipping a wire-bonding process of a light emitting diode chip in a package manufacturing process, as well as allowing for a significant reduction in the loss of a light emitting region.

According to an exemplary embodiment of the present inventive concept, a semiconductor light emitting device package may include: a package body having first and second electrode structures; and a light emitting diode chip mounted on the second electrode structure of the package body, the light emitting diode chip including: a support substrate, a light emitting structure including a second conductivity type semiconductor layer, an active layer and a first conductivity type semiconductor layer sequentially stacked on the support substrate, a transparent electrode layer disposed on the first conductivity type semiconductor layer, and an insulating layer disposed on at least a side surface of the light emitting structure. The transparent electrode layer and the first electrode structure may be connected to each other by a side electrode disposed on a side surface of the light emitting diode chip.

The side electrode may be disposed on respective side surfaces of the light emitting diode chip.

The side electrode may be disposed to cover at least one side surface of the light emitting diode chip.

The side electrode may be disposed to cover two or more side surfaces of the light emitting diode chip.

The side electrode may further include an extension electrode disposed to contact an edge of the transparent electrode layer.

The extension electrode may be disposed along a corner portion of the transparent electrode layer.

The extension electrode may further include an electrode finger portion intersecting with a central region of the transparent electrode layer.

The insulating layer may cover a region including the side surface of the light emitting structure.

The transparent electrode layer may be disposed to cover an upper surface of the first conductivity type semiconductor layer.

The transparent electrode layer may be patterned.

The pattern may have a plurality of openings through which portions of the first conductivity type semiconductor layer are exposed.

The plurality of openings may be arranged in grid form.

The side electrode may connect the transparent electrode layer and the first electrode structure to each other at the shortest distance therebetween.

The semiconductor light emitting device package may further include a lens part disposed to cover the light emitting diode chip.

According to another exemplary embodiment of the present inventive concept, a semiconductor light emitting device package may include: a package body having first and second electrode structures; and a light emitting diode chip mounted on the second electrode structure of the package body. The light emitting diode chip may include: a light emitting structure including a first conductivity type semiconductor layer, an active layer, and a second conductivity type semiconductor layer, the second conductivity type semiconductor layer being electrically connected to the second electrode structure, a transparent electrode layer disposed on the first conductivity type semiconductor layer, an insulating layer disposed on at least aside surface of the light emitting structure, and a side electrode electrically connecting the transparent electrode layer and the first electrode structure to each other and disposed on a surface of the insulating layer.

According to still another exemplary embodiment of the present inventive concept, a semiconductor light emitting device package may include: a package body having first and second electrode structures; a light emitting diode chip mounted on the package body and including a light emitting structure including first and second conductivity type semiconductor layers and an active layer interposed between the first and second conductivity type semiconductor layers; and a transparent electrode layer covering the first conductivity type semiconductor layer. The first conductivity type semiconductor layer and the first electrode structure may be electrically connected to each other via the transparent electrode layer and aside electrode disposed on aside surface of the light emitting diode chip.

The semiconductor light emitting device package may further include an insulating layer interposed between the side electrode and the light emitting structure. The insulating layer may be disposed on at least a side surface of the light emitting structure.

The side electrode may cover all side surfaces of the light emitting structure and may be a light reflective layer.

The side electrode may include an extension electrode which contacts an edge of the transparent electrode layer.

The side electrode may connect the transparent electrode layer and the first electrode structure to each other at the shortest distance therebetween.

### BRIEF DESCRIPTION OF DRAWINGS

The above and other aspects, features and other advantages of the present inventive concept will be more clearly understood from the following detailed description taken in conjunction with the accompanying drawings, in which:

FIG. 1 is a perspective view of a semiconductor light emitting device package according to an exemplary embodiment of the present inventive concept;

FIG. 2 is a side cross-sectional view of the semiconductor light emitting device package of FIG. 1, taken along line A-A′;

FIG. 3 is a modified example of an exemplary embodiment of the present inventive concept;

FIGS. 4A through 4D are plan views illustrating various forms of a transparent electrode layer of FIG. 1;

FIGS. 5A through 5D are plan views illustrating various forms of an extension electrode of FIG. 1;

FIGS. 6 through 13 are views of respective main processes, illustrating a process of manufacturing the semiconductor light emitting device package of FIG. 1;

FIGS. 14 and 15 are views each illustrating an example of applying the semiconductor light emitting device package according to an exemplary embodiment of the present inventive concept to a backlight unit; and

FIGS. 16 and 17 are views each illustrating an example of applying the semiconductor light emitting device package according to an exemplary embodiment of the present inventive concept to a lighting device.

### DETAILED DESCRIPTION

Exemplary embodiments of the present inventive concept will now be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

In the specification, the terms ‘above’, ‘upper portion’, ‘upper surface’, ‘below’ lower portion′, ‘lower surface’ and the like, are used based on the drawings, and may actually be different depending on a direction in which a component is disposed.

First, a semiconductor light emitting device package 10 according to an exemplary embodiment of the present inventive concept will be described.

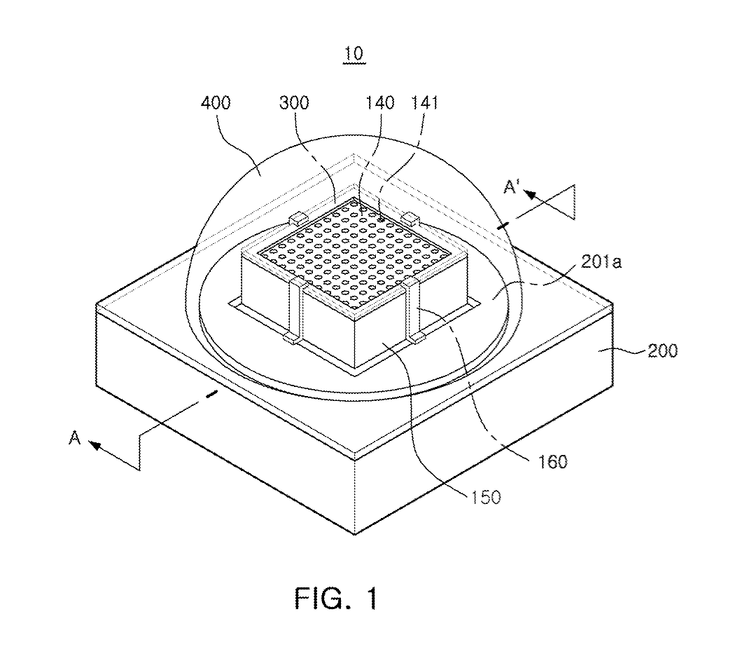

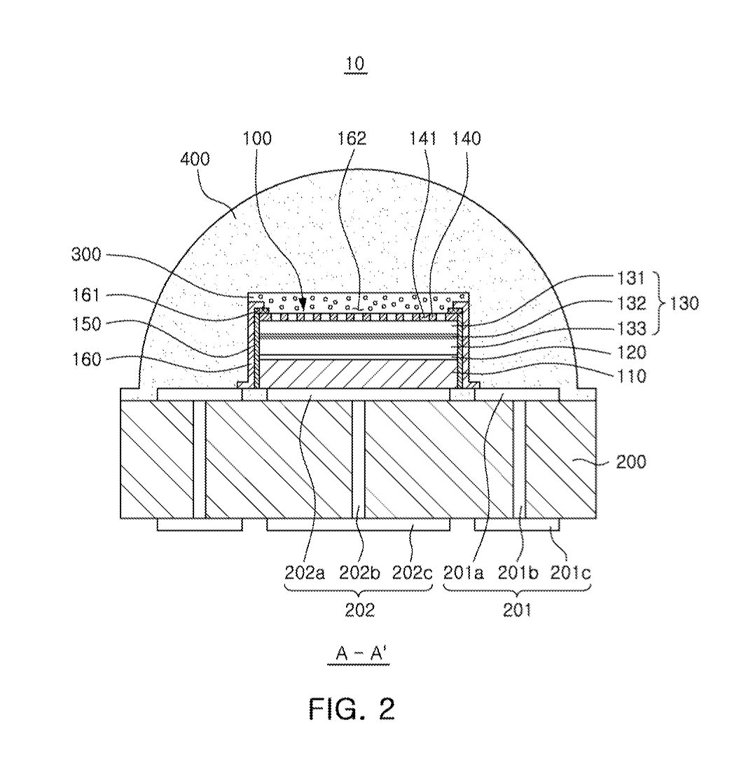

FIG. 1 is a perspective view of a semiconductor light emitting device package according to an exemplary embodiment of the present inventive concept. FIG. 2 is a side cross-sectional view of the semiconductor light emitting device package of FIG. 1, taken along line A-A′.

As illustrated in FIGS. 1 and 2, the semiconductor light emitting device package 10 according to the exemplary embodiment of the present inventive concept may include a package body 200 having first and second electrode structures 201 and 202, and a light emitting diode chip 100 mounted on the second electrode structure 202 of the package body 200, the light emitting diode chip 100 being connected to the first electrode structure 201 by a side electrode 160.

The first and second electrode structures 201 and 202 may be disposed on the package body 200, and the light emitting diode chip 100 may be mounted on the second electrode structure 202.

Specifically, the first and second electrode structures 201 and 202 may include first and second through electrodes 201b and 202b penetrating through one surface and the other surface of the package body 200 on which the light emitting diode chip 100 is mounted, and first and second upper electrode structures 201a and 202a and first and second lower electrode structures 201c and 202c respectively disposed on the one surface and the other surface of the package body 200 to which both ends of the first and second through electrodes 201b and 202b are exposed, such that the both surfaces of the package body 200 may be electrically connected to each other. For example, the first upper electrode structure 201a and the first lower electrode structure 201c are electrically connected to each other via the first through electrode 201b, and the second upper electrode structure 202a and the second lower electrode structure 202c are electrically connected to each other via the second through electrode 202b. However, shapes of the first and second electrode structures 201 and 202 are not limited to those illustrated in the exemplary embodiment, and may be modified in various manners.

Here, the package body 200 may be formed of an organic resin material containing epoxy, triazine, silicone, polyimide or the like and other organic resin materials, but in order to improve heat radiation characteristics and light emission efficiency, the package body 200 may be formed of a ceramic material having characteristics such as high degrees of heat resistance, thermal conductivity, reflection efficiency, and the like, for example, a material such as Al₂O₃, AlN or the like. However, the material of the package body 200 is not limited thereto, and in consideration of heat radiation characteristics and electrical connection relationships of the light emitting diode chip 100, the package body 200 may be formed of various materials.

In addition to the ceramic substrate described above, a printed circuit board, a lead frame or the like may be used as the package body 200 according to the exemplary embodiment. In addition, the package body 200 may have a cup shape in order to increase reflection efficiency of light.

The light emitting diode chip 100 may be mounted on the package body 200 and include a light emitting structure 130 disposed on a support substrate 110, a transparent electrode layer 140 disposed on one surface of the light emitting structure 130, and insulating layers 150 disposed on side surfaces of the support substrate 110 and the light emitting structure 130.

The support substrate 110 itself may be a substrate formed of a conductive material or may be an insulating substrate provided with an electrode structure such as conductive vias connected to each other in a vertical direction.

In a case in which the support substrate 110 is formed of the conductive material, the support substrate 110 may be a substrate formed of Si, GaAs, GaP, AlGaInP, Ge, SiSe, GaN, AlInGaN or InGaN, or may be formed by attaching a substrate formed of a single metal such as Al, Zn, Ag, W, Ti, Ni, Au, Mo, Pt, Pd, Cu, Cr or Fe or an alloy substrate thereof such as Si—Al to the light emitting structure. In an exemplary embodiment of the present inventive concept, a Si—Al alloy substrate may be used.

The support substrate 110 may serve as a p-side electrode applying power to a second conductivity type semiconductor layer 133 as well as serving to support the light emitting structure 130.

In this case, the support substrate 110 may be attached to the light emitting structure 130 through a conductive adhesive layer 120, and the support substrate 110 may be formed through a plating process. That is, the support substrate 110 may be formed by plating a metal such as Cu, Ni or the like onto the light emitting structure 130.

The conductive adhesive layer 120 may be provided to enforce contact between the second conductivity type semiconductor layer 133 and the support substrate 110 and in general, may be formed of a conductive material having adhesive properties. The conductive adhesive layer 120 may be formed of Au or may also be formed of a eutectic metal such as Au/Ge, Au/In, Au/Sn, Pb/Sn or the like. Furthermore, the conductive adhesive layer 120 may be formed of a conductive organic material.

The light emitting structure 130 may include the second conductivity type semiconductor layer 133, an active layer 132, and a first conductivity type semiconductor layer 131 sequentially disposed on the support substrate 110. The first and second conductivity type semiconductor layers 131 and 133 may be n-type and p-type semiconductor layers, respectively, and may be formed of a nitride semiconductor. Thus, in the exemplary embodiment, it may be understood that the first and second conductivity type semiconductor layers 131 and 133 may refer to an n-type nitride semiconductor layer and a p-type nitride semiconductor layer, respectively, but are not limited thereto. The first and second conductivity type semiconductor layers 131 and 133 may have a compositional formula of AlₓIn_{y}Ga_{(1-x-y)}N (where, 0≦x<1, 0≦y<1, 0≦x+y<1) and a material having the compositional formula may be, for example, GaN, AlGaN, InGaN or the like.

The active layer 132, a layer emitting visible light (in a wavelength range of about 350 nm to 680 nm), may be configured as an undoped nitride semiconductor layer having a single quantum well (SQW) structure or a multiple quantum well (MQW) structure. The active layer 132 may be formed to have a MQW structure in which quantum barrier and quantum well layers having a composition of AlₓIn_{y}Ga_{1-x-y}N (0≦x<1, 0≦y<1, 0≦x+y<1) are alternately stacked to have a predetermined band gap. Electrons and electron holes are recombined due to the quantum well layer to thereby emit light. The MQW structure may be, for example, an InGaN/GaN structure. The first and second conductivity type semiconductor layers 131 and 133 and the active layer 132 may be formed using a crystal growth process such as metal organic chemical vapor deposition (MOCVD), molecular beam epitaxy (MBE), hydride vapor phase epitaxy (HVPE), or the like, commonly known in the technical field.

The light emitting diode chip 100 may be a so called “vertical structure type light emitting diode chip” in which an n-side electrode and a p-side electrode applying power to the first conductivity type semiconductor layer 131 and the second conductivity type semiconductor layer 133, respectively, are disposed on opposite surfaces of the light emitting diode chip 100, and may further include a buffer layer for reducing a crystal defect during a growth process of the semiconductor layer.

The transparent electrode layer 140 may be disposed on the first conductivity type semiconductor layer 131 of the light emitting structure 130. The transparent electrode layer may be formed of a transparent conductive oxide (TCO) material such as indium tin oxide (ITO), zinc-doped indium tin oxide (ZITO), zinc indium oxide (ZIO), gallium indium oxide (GIO), zinc tin oxide (ZTO), fluorine-doped tin oxide (FTO), aluminum-doped zinc oxide (AZO), gallium-doped zinc oxide (GZO), In₄Sn₃O₁₂ or Zn₍₁₋ₓ₎MgₓO(Zinc Magnesium Oxide, 0≦x<1). If necessary, the transparent electrode layer may be formed of graphene.

The transparent electrode layer 140 may diffuse a current introduced from the side electrode 160 to thereby prevent the concentration of current density in the vicinity of the side electrode 160. In the exemplary embodiment, the transparent electrode layer 140 may be formed between the side electrode 160 and the first conductivity type semiconductor layer 131, whereby the current may be further efficiently diffused. The transparent electrode layer 140 may be formed to cover the entirety of an upper surface of the first conductivity type semiconductor layer 131, but may be formed to cover only a portion of the upper surface of the first conductivity type semiconductor layer 131. In addition, a plurality of openings 141 may be formed in the transparent electrode layer 140, whereby light transmittance properties may be further improved.

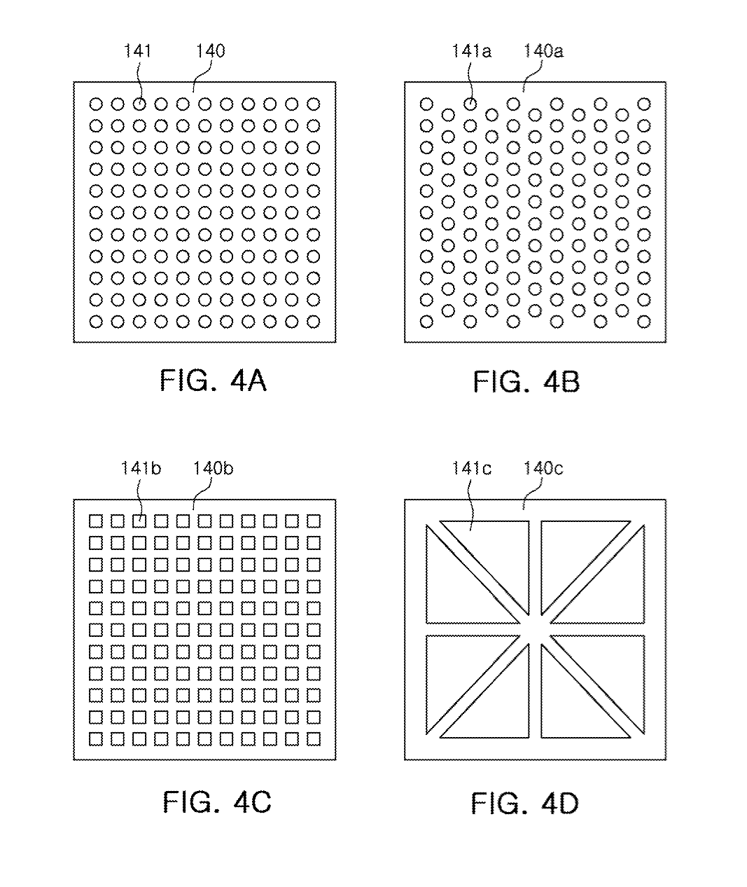

The transparent electrode layer 140 may be modified in various manners. FIGS. 4A through 4D are plan views illustrating various forms of the transparent electrode layer 140.

As illustrated in FIG. 4A, when viewed from an upper surface of the light emitting diode chip 100, the transparent electrode layer 140 may be formed such that the plurality of openings 141 may be arranged at regular intervals. Shapes and arrangements of the openings 141 may be variously modified. The openings 141 may be variously formed such as having circular shapes, polygonal shapes or stripe shapes, and may be arranged in grid form or be arranged to be offset from each other.

FIG. 4B illustrates an example of alternately arranging openings 141a of a transparent electrode layer 140a in a transverse direction and FIG. 4C illustrates an example of forming quadrangular openings 141b of a transparent electrode layer 140b. FIG. 4D illustrates an example of forming triangular openings 141c of a transparent electrode layer 140c, the triangular openings 141c being radially arranged toward a central region of the transparent electrode layer 140c.

An extension electrode 161 may be further formed on the transparent electrode layer 140. The extension electrode 161 may be formed in an edge of the transparent electrode layer 140 such that the current applied from the side electrode 160 to be described later may be easily diffused to the transparent electrode layer 140.

The extension electrode 161 may be formed of Au, Ag, Al, Ti, W, Cu, Sn, Ni, Pt, Cr, Sn, TiW, or AuSn, or a material containing a eutectic metal thereof. The extension electrode 161 may be formed as a single layer or a plurality of layers. The extension electrode 161 may be formed of the same material as that of the side electrode 160 to be described later.

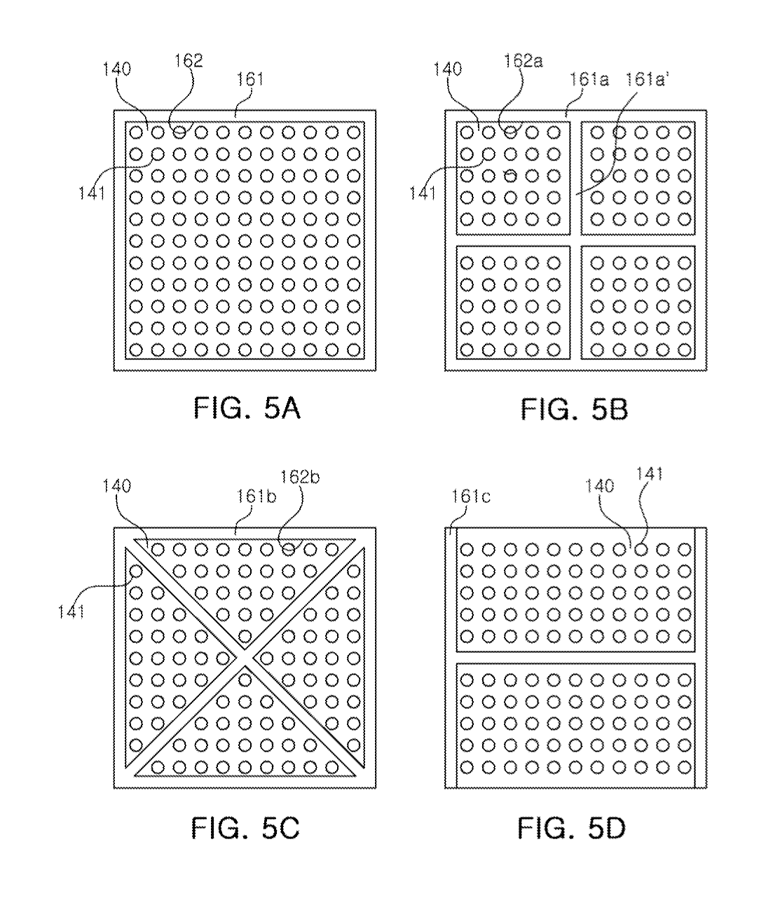

The extension electrode 161 may be modified in various forms. FIGS. 5A through 5D are plan views illustrating various forms of the extension electrode 161.

As illustrated in FIG. 5A, when viewed from the upper surface of the light emitting diode chip 100, the extension electrode 161 may be disposed in the edge of the transparent electrode layer 140 so as to have a quadrangular opening 162. A shape and an arrangement of the opening 162 may be variously modified. The opening 162 may be variously shaped such as having a circular shape, a polygonal shape or a stripe shape. If necessary, the opening 162 may be formed of a plurality of openings, and the plurality of openings may be arranged in grid form or be arranged to be offset from each other.

FIG. 5B illustrates an example of further including an electrode finger portion 161a′ intersecting with a central region of the transparent electrode layer 140 in such a manner that openings 162a of an extension electrode 161a are formed in a quadrangular shape and are arranged at regular intervals. FIG. 5C illustrates an example of forming triangular openings 162b of an extension electrode 161b. FIG. 5D illustrates an example of forming an H-shaped opening such that an extension electrode 161c is only formed in a partial edge of the transparent electrode layer 140.

The extension electrode 161 may be disposed separately from the side electrode 160 but may be integrally formed with the side electrode 160 in a single process. The extension electrode 161 is not necessarily required and if necessary, may be omitted.

The insulating layers 150 may be disposed on side surfaces of the light emitting diode chip 100. The insulating layers 150 may be disposed on at least side surfaces of the light emitting structure 130, in the side surfaces of the light emitting diode chip 100.

As described above, in the case that the support substrate 110 is formed as a conductive substrate, the insulating layers 150 may be disposed in regions including the side surfaces of the support substrate 110 and the side surfaces of the light emitting structure 130. In this case, the insulating layers 150 may insulate the support substrate 110 and the light emitting structure 130 from the side electrode 160 to prevent the current applied to the first conductivity type semiconductor layer 131 from being leaked to the second conductivity type semiconductor layer 133 or the support substrate 110.

In addition, in the case that the support substrate 110 is formed as an insulating substrate, the insulating layers 150 may be limitedly disposed in regions including the side surfaces of the light emitting structure 130. In this case, since the support substrate 110 has insulation properties, the support substrate 110 and the light emitting structure 130 may be insulated from the side electrode 160 even in the case that the insulating layer 150 is not disposed on the side surface of the support substrate 110. Therefore, a leakage of the current applied to the first conductivity type semiconductor layer 131 into the second conductivity type semiconductor layer 133 may be prevented.

Each of the insulating layers 150 may be disposed such that the side electrode 160 to be described later includes at least a contact region coming into contact with the side surface of the light emitting diode chip 100, and may be disposed to cover a surface in which the side electrode 160 is disposed, among the side surfaces of the light emitting diode chip 100. In addition, the insulating layers 150 may be disposed to cover respective side surfaces of the light emitting diode chip 100. When the side surface of the transparent electrode layer 140 is covered with the insulating layer 150 as described above, a phenomenon in which the side electrode 160 directly contacts the transparent electrode layer 140 without passing through the extension electrode 161 may be prevented, such that current diffusion may be advantageous.

The insulating layer 150 may be formed of an insulating material such as SiO₂, SiN, TiO₂, Si₃N₄, Al₂O₃, TiN, AlN, ZrO₂, TiAlN, or TiSiN.

The side electrode 160 may connect the transparent electrode layer 140 and the first electrode structure 201 to each other and may be disposed on the side surface of the light emitting diode chip 100. Specifically, one end of the side electrode 160 may be connected to at least one region of the transparent electrode layer 140. In this case, the side electrode 160 may be connected to the transparent electrode layer 140 via the extension electrode 161. In addition, the other end of the side electrode 160 may be extended to the side surface of the light emitting structure 130 and be connected to the first electrode structure 201.

The side electrode 160 may be disposed in the form of a stripe connecting the transparent electrode layer 140 and the first electrode structure 201 to each other at the shortest distance therebetween on respective side surfaces of the light emitting diode chip 100, whereby a current path between the transparent electrode layer 140 and the first electrode structure 201 may be minimized.

The side electrode 160 may serve as an n-side electrode applying power to the first conductivity type semiconductor layer 131. The side electrode 160 may be formed of Au, Ag, Al, Ti, W, Cu, Sn, Ni, Pt, Cr, Sn, TiW, or AuSn, or a material containing a eutectic metal thereof. The side electrode 160 may be formed as a single layer or a plurality of layers. The side electrode 160 may be formed of the same material as that of the extension electrode 161.

FIGS. 1 and 2 illustrate a case in which the side electrode 160 is disposed in a stripe shape on respective side surfaces of the light emitting diode chip 100, but are not limited thereto. The disposition form of the side electrode 160 may be variously modified.

For example, the side electrode 160 may be configured not to be disposed on at least one side surface of the light emitting diode chip 100. In addition, the side electrode 160 may be formed to cover at least one surface of the light emitting diode chip 100.

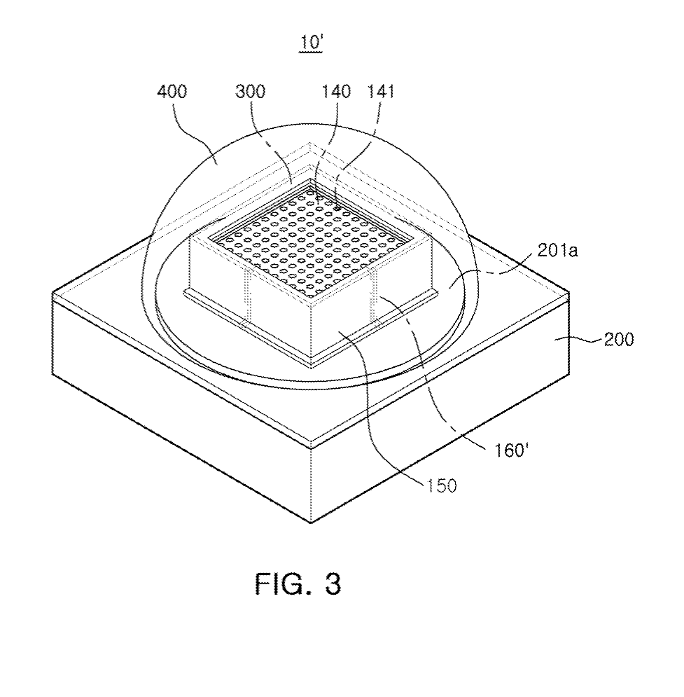

FIG. 3 is a modified example of an exemplary embodiment of the present inventive concept and illustrates a case in which side electrodes 160′ are disposed to cover all side surfaces of the light emitting diode chip 100. In this manner, when the side electrodes 160′ are disposed to cover all side surfaces of the light emitting diode chip 100, the side electrodes 160′ may allow light emitted from the light emitting diode chip 100 to be reflected in a direction upwardly from the light emitting diode chip 100, thereby serving as a reflective layer. Thus, light extraction efficiency of a semiconductor light emitting device package 10′ may be further improved.

As illustrated in FIG. 2, a wavelength conversion layer 300 may be disposed on the upper surface of the light emitting diode chip 100. The wavelength conversion layer 300 may contain phosphors or quantum dots. In addition, the wavelength conversion layer 300 may be formed as a sheet having a substantially constant thickness, and may be a film in which substances such as phosphors are dispersed in a B-stage material of which the phase is varied between a B-stage state at a room temperature and a movable state at the time of heating. Specifically, the B-stage material may be B-stage silicone.

The wavelength conversion layer 300 may have a structure in which a single layer is disposed or a plurality of layers are stacked. In the event that the wavelength conversion layer 300 is formed of a plurality of layers, different types of phosphors and the like may be contained in the respective layers.

The wavelength conversion layer 300 may be formed by combining phosphors, quantum dots or the like with a B-stage resin material and for example, may be a B-stage composite material formed by combining phosphors with a polymer binder containing a resin, a hardener, a hardening catalyst or the like.

Examples of the phosphors may include garnet-based phosphors (YAG, TAG, and LuAG), silicate-based phosphors, nitride-based phosphors, sulfide-based phosphors, oxide-based phosphors and the like, and the phosphors may be configured of single species or a plurality of species mixed in a predetermined ratio.

The resin used in the wavelength conversion layer 300 may be a resin having high degrees of adhesiveness, light transmittance, heat resistance, photo-refraction, and moisture resistance properties and the like, and examples of the resin may be epoxy resins or silicone which is an inorganic polymer. In order to secure a high degree of adhesiveness, for example, a silane based material may be employed as an additive for improving adhesiveness.

A lens part 400 may be further formed on the wavelength conversion layer 300. The lens part 400 may be disposed to enclose the light emitting structure 130 and the wavelength conversion layer 300. The lens part 400 may control a distribution of light emitted from the light emitting structure 130 by adjusting a shape of a surface thereof. The lens part 400 may be formed of a light transmissive material, for example, an insulating resin having translucency, such as silicone, modified silicone, epoxy, urethane, oxetane, acrylics, polycarbonate, or polyimide and compositions containing combinations thereof. However, the material of the lens part 400 is not limited thereto, and may be a material having excellent light transmissive properties such as glass, silica gel or the like.

In the case of the semiconductor light emitting device package 10 employing the side electrode 160 having such a structure, a manufacturing process thereof may be simplified as compared to the case of a vertical structure type light emitting device package according to the related art and the loss of a light emitting region may be significantly reduced. With regard to this, a detailed description thereof will be followed.

In a vertical structure type light emitting device package according to the related art, power is applied thereto by connecting a package substrate and a first conductivity type semiconductor layer of a light emitting diode chip to each other through wire-bonding. In order to perform such wire-bonding, an electrode pad needs to be formed on the first conductivity type semiconductor layer of the light emitting diode chip. The electrode pad may reduce a light emitting region of the light emitting diode chip to result in a decrease in light extraction efficiency, and a wire bonded to the electrode pad may pass through an upper portion of the light emitting diode chip and be connected to the package substrate. Thus, the wire bonded to the electrode pad may absorb or reflect light emitted from the light emitting diode chip to cause a reduction in light extraction efficiency. In addition, since wires are individually bonded to respective light emitting diode chips, it may be infeasible to simultaneously manufacture large numbers of semiconductor light emitting device packages to thereby cause an increase in manufacturing time.

In order to solve such defects of the vertical structure type light emitting device package according to the related art, in an exemplary embodiment of the present inventive concept, power may be applied to the light emitting diode chip 100 without wire-bonding. Specifically, the reduction of the light emitting region due to the electrode pad of the light emitting diode chip for wire-bonding may be prevented by disposing the side electrode 160 on the side surfaces of the light emitting diode chip 100. In addition, since a separate wire is unnecessary, a phenomenon in which light emitted from the light emitting diode chip is absorbed into or reflected from the wire may be fundamentally prevented. Moreover, since the side electrodes may be formed on the light emitting diode chip 100 through a deposition process, it may be feasible to simultaneously manufacture large numbers of semiconductor light emitting device packages. Thus, time required for manufacturing semiconductor light emitting device packages may be remarkably reduced.

Next, a manufacturing process of the semiconductor light emitting device package 10 according to an exemplary embodiment of the present inventive concept will be described.

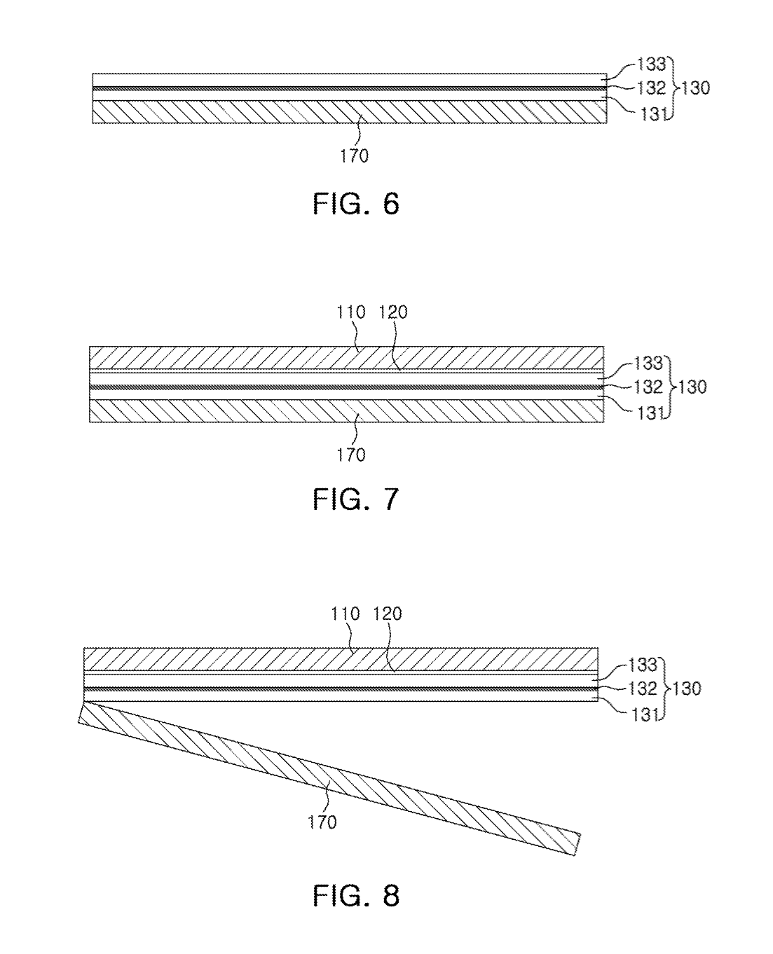

FIGS. 6 through 13 are views of respective main processes, illustrating a process of manufacturing the semiconductor light emitting device package of FIG. 1.

First, as illustrated in FIG. 6, the first conductivity type semiconductor layer 131, the active layer 132, and the second conductivity type semiconductor layer 133 are sequentially stacked on an upper portion of a growth substrate 170 to form the light emitting structure 130.

The growth substrate 170 may be provided as a semiconductor growth substrate and be formed of a material such as sapphire, SiC, MgAl₂O₄, MgO, LiAlO₂, LiGaO₂, GaN, Si or the like. In particular, sapphire widely used as a nitride semiconductor growth substrate may be a crystal having electrical insulating properties and Hex a-Rhombo R3c symmetry. The sapphire may have a lattice constant of 13.001 Å in a C-axis direction and a lattice constant of 4.758 Å in an A-axis direction and may include a C (0001) plane, an A (11-20) plane, an R (1-102) plane, and the like. In this case, the C plane is mainly used as a nitride growth substrate because the C plane relatively facilitates the growth of a nitride film and is stable at high temperature.

Meanwhile, although not illustrated in the drawings, a plurality of unevenness structures may be formed on an upper surface of the growth substrate 170, that is, a growth surface of the semiconductor layers. Due to the unevenness structures, crystalline properties and light emission efficiency of the semiconductor layers may be improved.

The first conductivity type semiconductor layer 131, the active layer 132, and the second conductivity type semiconductor layer 133 may be sequentially stacked on the growth substrate 170, using a process such as metal organic chemical vapor deposition (MOCVD), hydride vapor phase epitaxy (HVPE), molecular beam epitaxy (MBE), or the like.

Then, as illustrated in FIG. 7, the support substrate 110 may be attached to the second conductivity type semiconductor layer 133 of the light emitting structure 130. In this case, the support substrate 110 may be attached to the light emitting structure 130 through the conductive adhesive layer 120, and the support substrate 110 may be formed through a plating process. That is, the support substrate 110 may be formed by plating a metal such as Cu, Ni or the like onto the light emitting structure 130.

Then, as illustrated in FIG. 8, the growth substrate 170 may be separated from the first conductivity type semiconductor layer 131 by a laser lift-off (LLO) method.

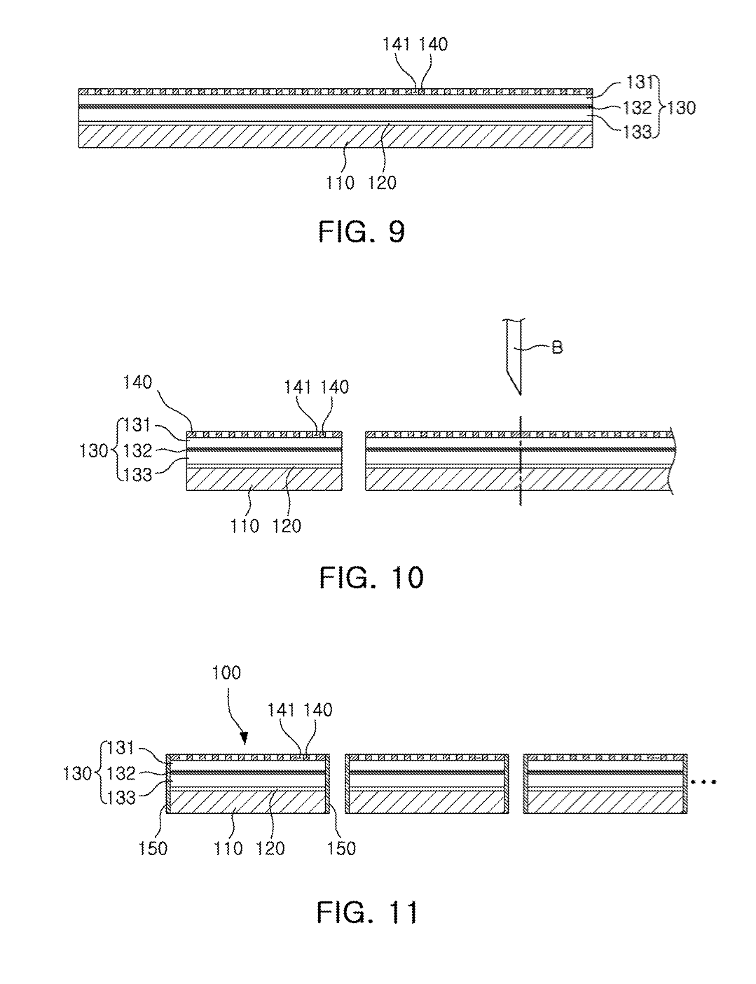

Next, as illustrated in FIG. 9, the transparent electrode layer 140 may be disposed on the first conductivity type semiconductor layer 131. As described above, the transparent electrode layer 140 may include the plurality of openings 141, whereby an amount in which light emitted from the active layer 132 penetrates through the transparent electrode layer 140 may be increased.

The transparent electrode layer 140 may be formed by depositing or sputtering a transparent conductive oxide (TCO) material such as indium tin oxide (ITO), zinc-doped indium tin oxide (ZITO), zinc indium oxide (ZIO), gallium indium oxide (GIO), zinc tin oxide (ZTO), fluorine-doped tin oxide (FTO)), aluminum-doped zinc oxide (AZO), gallium-doped zinc oxide (GZO), In₄Sn₃O₁₂ or Zn₍₁₋ₓ₎MgₓO (Zinc Magnesium Oxide, 0≦x<1). If necessary, the transparent electrode layer may be formed of graphene.

Next, as illustrated in FIG. 10, the support substrate 110, the light emitting structure 130 and the transparent electrode layer 140 may be separated into individual elements using a blade B. As illustrated in FIG. 11, the insulating layers 150 may be deposited on the side surfaces of the individual elements. The insulating layers 150 may be disposed in regions including the side surfaces of the support substrate 110 and the side surfaces of the light emitting structure 130. When the insulating layers 150 are disposed on the side surfaces of the individual elements, it may be possible to prevent the current applied to the first conductivity type semiconductor layer 131 from being leaked to the second conductivity type semiconductor layer 133 or the support substrate 110.

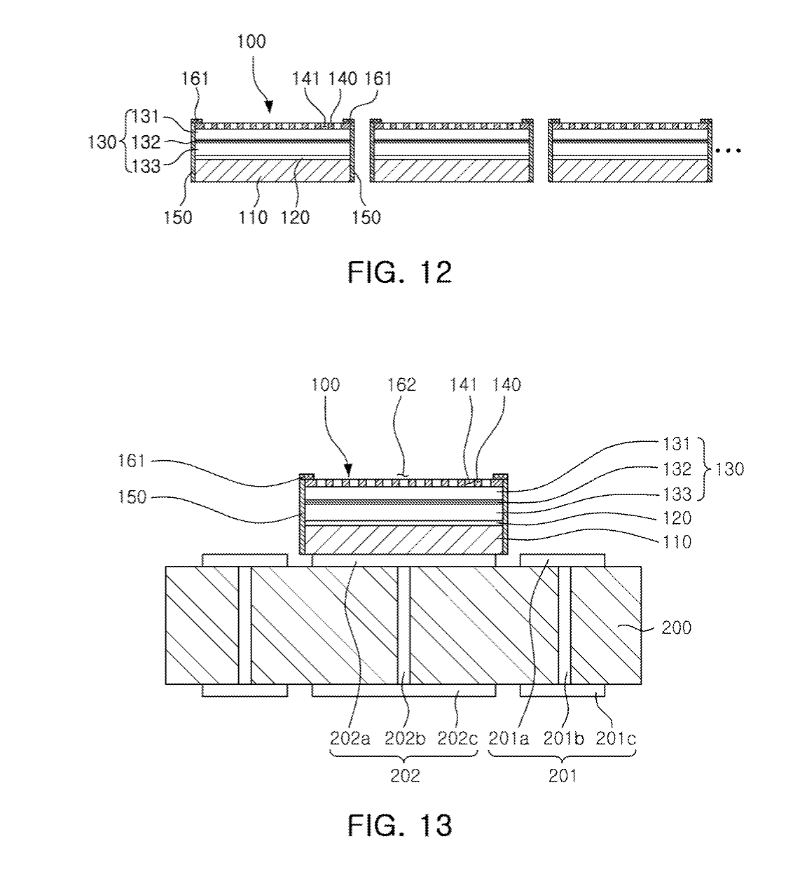

Next, as illustrated in FIG. 12, the extension electrode 161 may be disposed on the transparent electrode layer 140 to manufacture the light emitting diode chip 100. The extension electrode 161 may be formed in an edge of the transparent electrode layer 140 such that a current applied from the side electrode 160 may be easily diffused to the transparent electrode layer 140.

The extension electrode 161 may be formed by depositing or sputtering Au, Ag, Al, Ti, W, Cu, Sn, Ni, Pt, Cr, Sn, TiW, or AuSn, or a material containing a eutectic metal thereof. The extension electrode 161 may be formed as a single layer or a plurality of layers. The extension electrode 161 may be formed of the same material as that of the side electrode 160. In addition, the extension electrode 161 may not be separately formed and may be integrally formed with the side electrode 160 in the subsequent process.

Next, as illustrated in FIG. 13, the light emitting diode chip 100 may be mounted on the second electrode structure 202 of the prepared package body 200, such that the second electrode structure 202 may be electrically connected to the support substrate 110 of the light emitting diode chip 100.

Next, as illustrated in FIG. 2, the side electrode 160 may be disposed on the side surfaces of the light emitting diode chip 100. The side electrode 160 may be formed by depositing or sputtering Au, Ag, Al, Ti, W, Cu, Sn, Ni, Pt, Cr, Sn, TiW, or AuSn, or a material containing a eutectic metal thereof. The side electrode 160 may be formed as a single layer or a plurality of layers. Further, in this process, the extension electrode 161 as describe above may be formed simultaneously with the side electrode 160 through a single process.

Subsequently, the wavelength conversion layer 300 may be formed on the light emitting diode chip 100 and the lens part 400 may be attached to the wavelength conversion layer 300, thereby completing the semiconductor light emitting device package 10 of FIG. 1.

The semiconductor light emitting device package may be usefully applied to various application products.

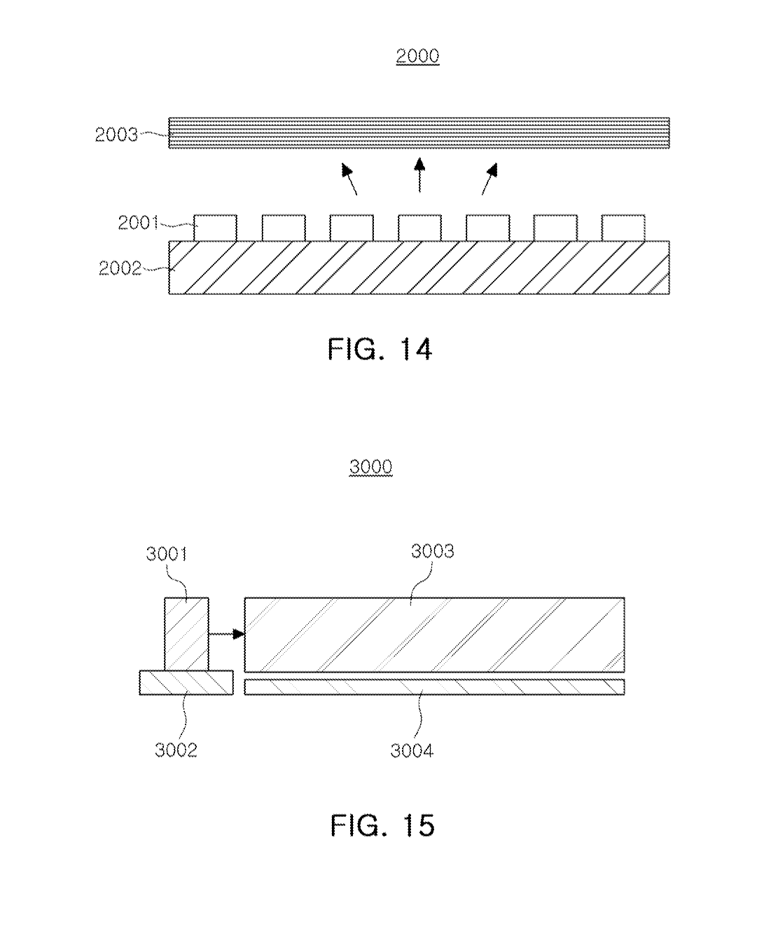

FIGS. 14 and 15 are views each illustrating an example of applying the semiconductor light emitting device package according to the exemplary embodiment of the present inventive concept to a backlight unit.

Referring to FIG. 14, a backlight unit 2000 includes a light source 2001 mounted on a substrate 2002 and at least one optical sheet 2003 disposed thereabove. The light source 2001 may be a semiconductor light emitting device package having a structure the same as or similar to that of the semiconductor light emitting device package 10 of FIG. 1 or 10′ of FIG. 3, or may be used by directly mounting a light emitting diode chip on the substrate 2002 (a so called a chip-on-board (COB) type LED).

The light source 2001 in the backlight unit 2000 of FIG. 14 emits light toward a liquid crystal display (LCD) device disposed thereabove. On the other hand, a light source 3001 mounted on a substrate 3002 in a backlight unit 3000 according to another embodiment illustrated in FIG. 15 emits light laterally, and the emitted light is incident to a light guide plate 3003 and may be converted into the form of a surface light source. The light having passed through the light guide plate 3003 may be emitted upwardly and a reflective layer 3004 may be formed under a bottom surface of the light guide plate 3003 in order to improve light extraction efficiency.

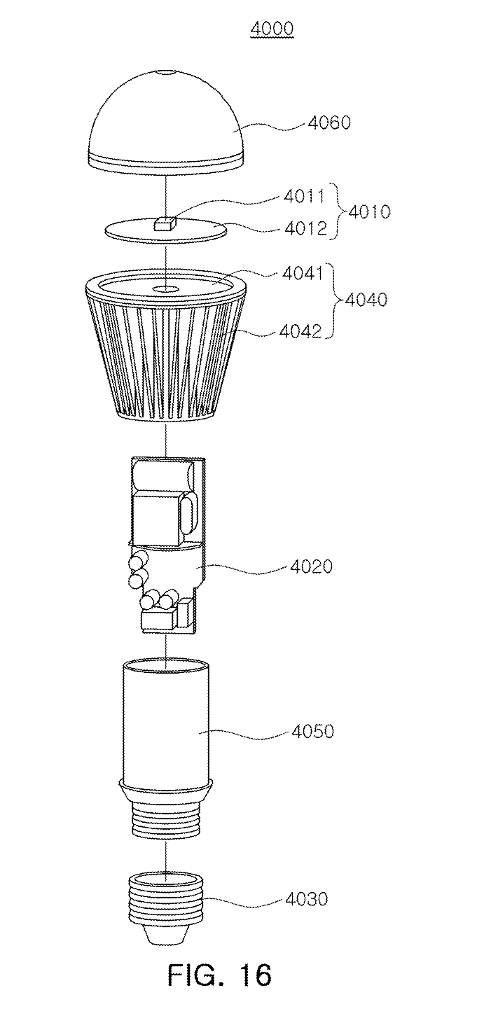

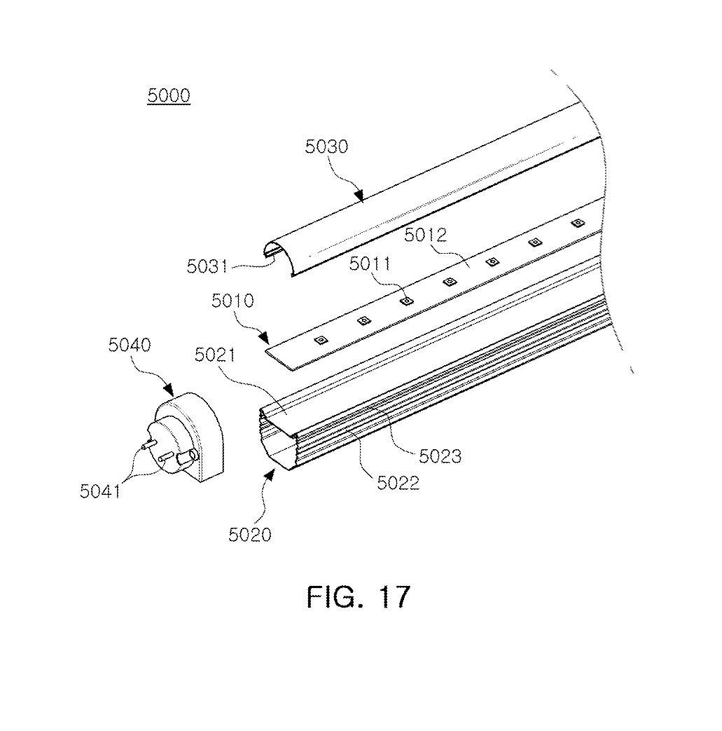

FIGS. 16 and 17 are views each illustrating an example of applying the semiconductor light emitting device package according to an exemplary embodiment of the present inventive concept to a lighting device.

Referring to FIG. 16, a lighting device 4000 is exemplified as a bulb-type lamp, and includes a light emitting module 4010, a driving unit 4020 and an external connector unit 4030. In addition, exterior structures such as an external housing 4040, an internal housing 4050, a cover unit 4060 and the like may be additionally included.

The light emitting module 4010 may include a semiconductor light emitting device package 4011 having a structure the same as or similar to that of the semiconductor light emitting device package 10 of FIG. 1 or 3 and a circuit board 4012 having the semiconductor light emitting device package 4011 mounted thereon. The embodiment illustrates the case in which a single semiconductor light emitting device package 4011 is mounted on the circuit board 4012; however, if necessary, a plurality of semiconductor light emitting device packages may be mounted thereon.

The external housing 4040 may serve as a heat radiating part, and include a heat sink plate 4041 in direct contact with the light emitting module 4010 to improve the dissipation of heat and heat radiating fins 4042 covering a lateral surface of the external housing 4040. The cover unit 4060 may be disposed above the light emitting module 4010 and may have a convex lens shape. The driving unit 4020 may be disposed inside the internal housing 4050 and may be connected to the external connector unit 4030 such as a socket structure to receive power from an external power source. In addition, the driving unit 4020 may convert the received power into a current source appropriate for driving the semiconductor light emitting device package 4011 of the light emitting module 4010 and supply the converted current source thereto. For example, the driving unit 4020 may be configured of an AC-DC converter, a rectifying circuit part, or the like.

Further, although not illustrated in the drawings, the lighting device 4000 may further include a communications module.

Referring to FIG. 17, a lighting device 5000 may be a bar type lamp, for example, and include a light emitting module 5010, a body part 5020, a cover part 5030 and a terminal part 5040.

The light emitting module 5010 may include a substrate 5012 and a plurality of semiconductor light emitting device packages 5011 mounted on the substrate 5012. The semiconductor light emitting device package 5011 may be the semiconductor light emitting device package 10 of FIG. 1 or 10′ of FIG. 3.

The body part 5020 may have the light emitting module 5010 mounted on one surface 5021 thereof to be fixed thereto and may emit heat generated from the light emitting module 5010 outwardly. Thus, the body part 5020 may be a sort of support structure and include a heat sink. A plurality of heat radiating fins 5022 for the radiation of heat may be formed on both side surfaces of the body part 5020 so as to be protruded therefrom.

The cover part 5030 may be coupled to catching grooves 5023 of the body part 5020 and may have a semicircular curved surface to enable light to be generally externally irradiated in a uniform manner e. Projection portions 5031 engaged with the catching grooves 5023 of the body part 5020 may be formed in a length direction of the cover part 5030 on the bottom surface thereof.

The terminal part 5040 may be provided in at least one open end of both ends of the body part 5020 in a length direction thereof and supply power to light emitting module 5010. The terminal part 5040 may include electrode pins 5041 outwardly protruded.

As set forth above, according to exemplary embodiments of the present inventive concept, a wire-bonding process of a semiconductor light emitting device package may be omitted. Further, the loss of a light emitting region due to the wire-bonding may be prevented.

While exemplary embodiments have been shown and described above, it will be apparent to those skilled in the art that modifications and variations could be made without departing from the spirit and scope of the present inventive concept as defined by the appended claims.

What is claimed is:

1. A semiconductor light emitting device package comprising:
a package body having first and second electrode structures; and
a light emitting diode chip mounted on the second electrode structure of the package body,
the light emitting diode chip including:
a support substrate,
a light emitting structure including a second conductivity type semiconductor layer, an active layer and a first conductivity type semiconductor layer sequentially stacked on the support substrate,
a transparent electrode layer disposed on the first conductivity type semiconductor layer, and
an insulating layer disposed on at least a side surface of the light emitting structure,
wherein the transparent electrode layer and the first electrode structure are connected to each other by a side electrode disposed on a side surface of the light emitting diode chip.

2. The semiconductor light emitting device package of claim 1, wherein the side electrode is disposed on respective side surfaces of the light emitting diode chip.

3. The semiconductor light emitting device package of claim 1, wherein the side electrode is disposed to cover at least one side surface of the light emitting diode chip.

4. The semiconductor light emitting device package of claim 3, wherein the side electrode is disposed to cover two or more side surfaces of the light emitting diode chip.

5. The semiconductor light emitting device package of claim 1, wherein the side electrode further includes an extension electrode disposed to contact an edge of the transparent electrode layer.

6. The semiconductor light emitting device package of claim 5, wherein the extension electrode is disposed along a corner portion of the transparent electrode layer.

7. The semiconductor light emitting device package of claim 5, wherein the extension electrode further includes an electrode finger portion intersecting with a central region of the transparent electrode layer.

8. The semiconductor light emitting device package of claim 1, wherein the insulating layer covers a region including the side surface of the light emitting structure.

9. The semiconductor light emitting device package of claim 1, wherein the transparent electrode layer is disposed to cover an upper surface of the first conductivity type semiconductor layer.

10. The semiconductor light emitting device package of claim 9, wherein the transparent electrode layer is patterned.

11. The semiconductor light emitting device package of claim 10, wherein the pattern has a plurality of openings through which portions of the first conductivity type semiconductor layer are exposed.

12. The semiconductor light emitting device package of claim 11, wherein the plurality of openings are arranged in grid form.

13. The semiconductor light emitting device package of claim 1, wherein the side electrode connects the transparent electrode layer and the first electrode structure to each other at the shortest distance therebetween.

14. The semiconductor light emitting device package of claim 1, further comprising a lens part disposed to cover the light emitting diode chip.

15. A semiconductor light emitting device package comprising:
a package body having first and second electrode structures; and
a light emitting diode chip mounted on the second electrode structure of the package body,
the light emitting diode chip including:
a light emitting structure including a first conductivity type semiconductor layer, an active layer, and a second conductivity type semiconductor layer, the second conductivity type semiconductor layer being electrically connected to the second electrode structure,
a transparent electrode layer disposed on the first conductivity type semiconductor layer,
an insulating layer disposed on at least a side surface of the light emitting structure, and
aside electrode electrically connecting the transparent electrode layer and the first electrode structure to each other and disposed on a surface of the insulating layer.

16. A semiconductor light emitting device package, comprising:
a package body having first and second electrode structures;
a light emitting diode chip mounted on the package body and including a light emitting structure including first and second conductivity type semiconductor layers and an active layer interposed between the first and second conductivity type semiconductor layers; and
a transparent electrode layer covering the first conductivity type semiconductor layer,
wherein the first conductivity type semiconductor layer and the first electrode structure are electrically connected to each other via the transparent electrode layer and a side electrode formed on a side surface of the light emitting diode chip.

17. The semiconductor light emitting device package of claim 16, further comprising an insulating layer interposed between the side electrode and the light emitting structure,
wherein the insulating layer is formed on at least a side surface of the light emitting structure.

18. The semiconductor light emitting device package of claim 16, wherein the side electrode covers all side surfaces of the light emitting structure and is alight reflective layer.

19. The semiconductor light emitting device package of claim 16, wherein the side electrode includes an extension electrode which contacts an edge of the transparent electrode layer.

20. The semiconductor light emitting device package of claim 16, wherein the side electrode connects the transparent electrode layer and the first electrode structure to each other at the shortest distance therebetween.
